(19) United States
(12) Patent Application Publication
(10) Pub. No.: US 2013/0108813 A1
(43) Pub. Date: May 2, 2013

(54) HOUSING FOR ELECTRONIC DEVICE AND METHOD OF FABRICATION

(71) Applicant: YONG-GANG ZHU, Shenzhen City (CN)

(72) Inventor: YONG-GANG ZHU, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/455,820

(22) Filed: Apr. 25, 2012

(30) Foreign Application Priority Data
Oct. 31, 2011 (CN) 201110337207.4

(51) Int. Cl. H05K 5/02; B23P 17/04

(52) U.S. Cl. 428/34.6; 29/527.4

(57) ABSTRACT

A housing for electronic device includes a metal substrate having a first ceramic coating and a second ceramic coating formed on an outer surface. The outer surface has a plurality of concave portions and a plurality of frame portions among the concave portions. The concave portions are divided into a plurality of first pattern areas and a plurality of second pattern areas. The first ceramic coating is directly formed in each first pattern area of the concave portions. The second ceramic coating is directly formed in each second pattern area of the concave portions. The second ceramic coating and the first ceramic coating have different appearances. A method for fabricating the present housing is also provided.

### BACKGROUND

1. Technical Field

The present disclosure relates to housings for electronic devices and a fabrication method for such housings.

2. Description of Related Art

Metals such as stainless steel, aluminum alloy, magnesium alloy, or titanium alloy, are usually used for making shells of portable electronic devices such as MP3 players, personal digital assistances (PDAs), and mobile phones.

Metal shells are usually electroplated or spray-painted to form decorative layers. However, these decorative layers often have insufficient wear-resistance.

Therefore, there is room for improvement within the art.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the disclosure. Moreover, in the drawing like reference numerals designate corresponding parts throughout the views.

FIG. 1 is a plan view of a housing according to an exemplary embodiment.

FIG. 2 is a cross-section view of the housing shown in FIG. 1 taken along line II-II.

FIG. 3 is a schematic cross-section view of a substrate of a housing according to an exemplary embodiment.

FIG. 4 is a schematic view showing a shield used in manufacturing a housing according to an exemplary embodiment.

### DETAILED DESCRIPTION

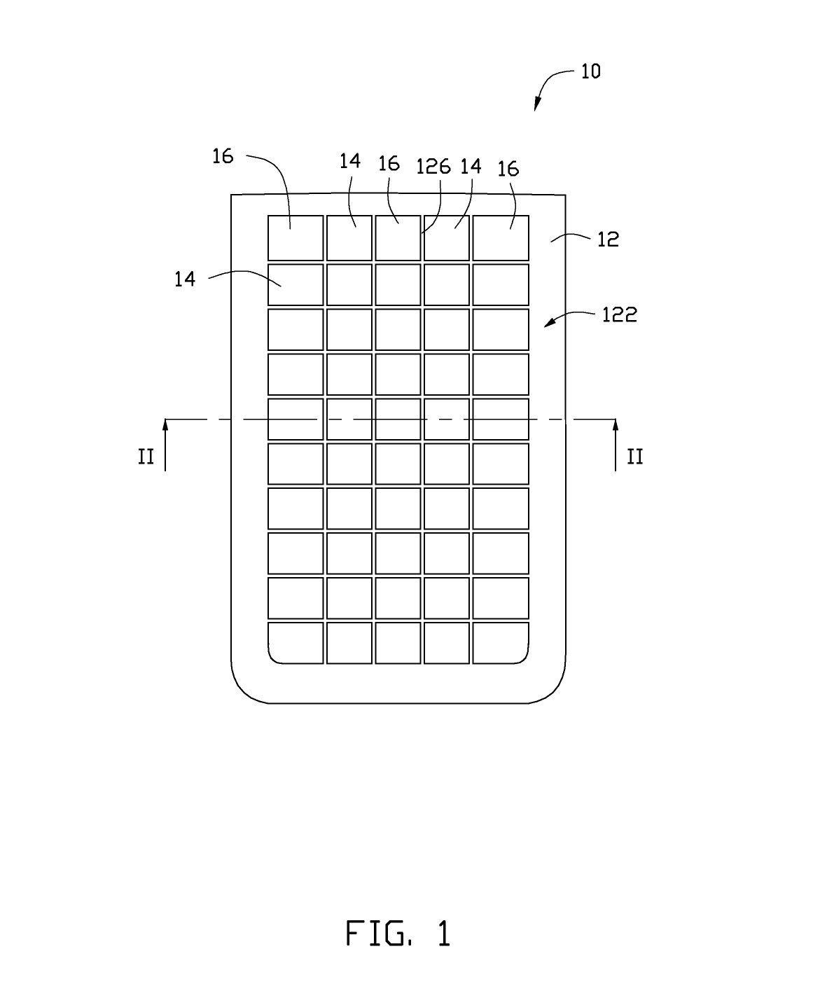

FIG. 1 shows a housing 10 for an electronic device (such as a mobile phone) according to an exemplary embodiment. The housing 10 includes a metal substrate 12 having a first ceramic coating 14 and a second ceramic coating 16 formed on the substrate 12. Both the first ceramic coating 14 and the second ceramic coating 16 are directly attached on the substrate 12. In other words, a surface of each first or second ceramic layer 14, 16 contacts a surface of the substrate 12.

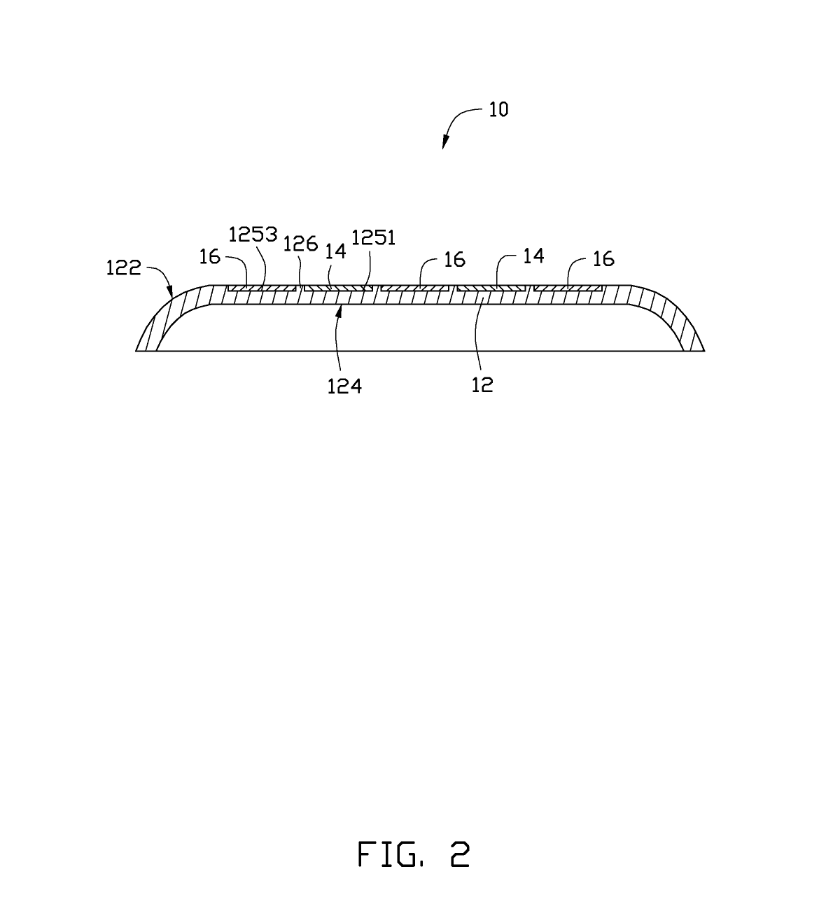

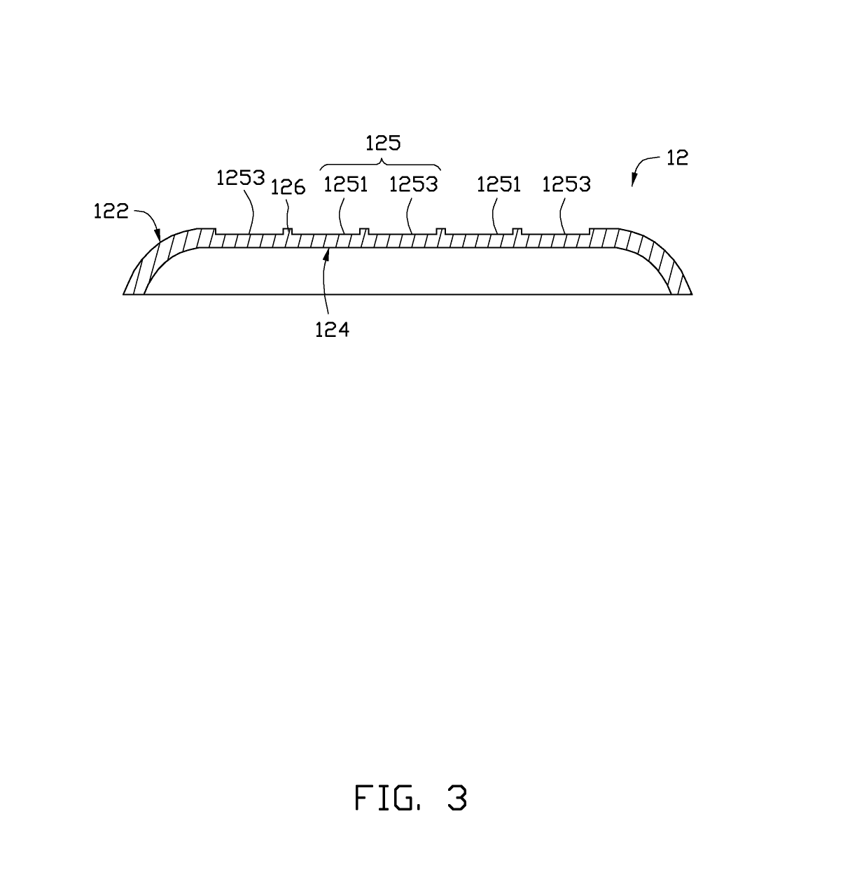

Referring to FIGS. 2 and 3, the substrate 12 may be stainless steel, aluminum alloy, or titanium alloy. The substrate 12 may have a thickness of about 0.4 mm to about 0.6 mm. In this exemplary embodiment, the substrate 12 is stainless steel and has a thickness of about 0.5 mm. The substrate 12 has an outer surface 122 and an inner surface 124 opposite to the outer surface 122.

The outer surface 122 has a plurality of concave portions 125 and a plurality of frame portions 126 among the concave portions 125.

The concave portions 125 are concave-down (i.e., extend into the outer surface 122 of the substrate 12) relative to the frame portions 126. The concave portions 125 are roughened and have a surface roughness Ra of about 1.3 μm to about 2.0 μm. The concave portions 125 are divided into a plurality of first pattern areas 1251 and a plurality of second pattern areas 1253. The first pattern areas 1251 and the second pattern areas 1253 can be alternatively arranged to cooperatively depict a first pattern by varying the appearance of their associated ceramic coatings, as described below.

Each frame portion 126 can have any desired shape. The frame portions 126 can be separately defined from each other. Alternatively, the frame portions 126 can intersect with each other. In this exemplary embodiment, the frame portions 126 are strip-shaped and intersect with each other. The frame portions 126 may cooperatively depict a second pattern, e.g., squares, diamonds, circles, etc.

The first ceramic coating 14 is directly formed in each first pattern area 1251 of the concave portions 125 by having a surface of the first ceramic coating 14 in contact with a surface of concave portion 125. The second ceramic coating 16 is directly formed in each second pattern area 1253 of the concave portions 125 by having a surface of the second ceramic coating 16 in contact with a surface of concave portion 125. The first ceramic coating 14 and the second ceramic coating 16 have different colors, thereby depicting the first pattern on the housing 10. The first ceramic coating 14 and the second ceramic coating 16 can be coplanar with the frame portions 126 to cooperatively form an outer surface of the housing 10 that is smooth to the touch.

Both the first ceramic coating 14 and the second ceramic coating 16 may be made of ceramic oxide material. For example, the first ceramic coating 14 and the second ceramic coating 16 are made of different ceramic materials selected from the group consisting of aluminum oxide (Al₂O₃), ferroferric oxide (Fe₃O₄), and titanium oxide (TiO₂). Since the above referred ceramic materials have different colors, the materials comprising the first ceramic coating 14 and the second ceramic coating 16 may be selected according to desired colors. For example, a coating made of Al₂O₃ can be white, a coating made of Fe₃O₄ can be black, and a coating made of obtain TiO₂ can be dark-blue. It is also possible that the first ceramic coating 14 and the second ceramic coating 16 are made of the same material, but containing different additives to produce different appearances, such as speckling or swirls. The first ceramic coating 14 and the second ceramic coating 16 each has a surface roughness Ra of about 0.1 μm to about 0.3 μm, and has a thickness of about 0.1 mm to about 0.12 mm.

An exemplary method for making the housing 10 may include the following steps.

A metal substrate 12 is provided. The substrate 12 has the outer surface 122 and the inner surface 124.

Portions of the outer surface 122 may be etched to be lower than other portions not etched. Accordingly, the etched portions form the concave portions 125, and other, non-etched portions form the frame portions 126. Chemical etching or laser etching may be used in this step. In this exemplary embodiment, chemical etching is selected. The chemical etching includes masking portions of the substrate 12 not to be etched using chemical resistant ink. The substrate 12 is then immersed in a chemical etchant. Portions of the substrate 12 not masked by the ink dissolve in the chemical etchant and the portions masked by ink do not. Therefore, the etched portions will be lower than the non-etched portions, thereby forming the concave portions 125. The ink is removed after the chemical etching. The etching may create an etching depth of about 0.1 mm to about 0.12 mm on the outer surface 122. The concave portions 125 are divided into the first pattern areas 1251 and the second pattern areas 1253.

The outer surface 122 may be roughened, for example by sandblasting. The outer surface 122 processed by this step achieves a surface roughness Ra of about 1.3 μm to about 2.0 μm. A roughened surface can improve the bonding between the substrate 12 and the subsequently formed first ceramic coating 14 and second ceramic coating 16. It is understood that this step can be omitted.

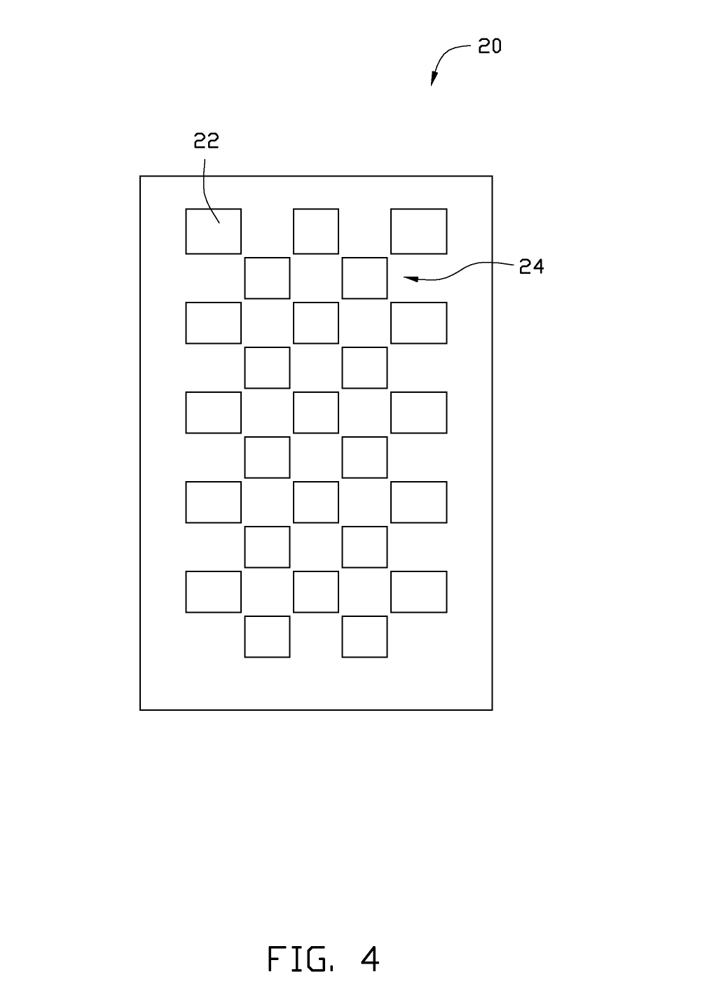

A first thermal spraying is applied to the outer surface 122, forming the first ceramic coating 14 in the first pattern areas 1251. It may be preferable to implement the thermal spraying approximately 4 hours after the roughening step. During the first thermal spraying step, a shield 20 (see FIG. 4) having a plurality of holes 22 may be used to mask the outer surface 122. The holes 22 cooperatively depict a pattern 24 corresponding to the first pattern areas 1251. Accordingly, the first pattern areas 1251 are uncovered by the holes 22, while other portions of the outer surface 122 are covered by the shield 20 and prevented from being sprayed. The first thermal spraying may be a flame spraying using oxygen-ethyne as fuel gas, air as conveying gas, and using a ceramic oxide material as spraying material. The ceramic oxide material may be one selected from the group consisting of Al₂O₃, Fe₃O₄, and TiO₂. The first ceramic coating 14 has an initial thickness equal to or lager than the etching depth. The initial thickness of the first ceramic coating 14 may be about 0.12 mm to about 0.14 μm. The shield 20 is removed when finished the first thermal spraying.

A second thermal spraying is applied to the outer surface 122 having the first ceramic coating 14, forming the second ceramic coating 16. The second ceramic coating 16 may initially cover the second pattern areas 1253, the first ceramic coating 14, and the frame portions 126. The second thermal spraying may be a flame spraying using oxygen-ethyne as fuel gas, air as conveying gas, and using a ceramic oxide material as spraying material. The ceramic oxide material for the second thermal spraying may be one selected from the group consisting of Al₂O₃, Fe₃O₄, and TiO₂. The spraying materials for the second thermal spraying and the first thermal spraying are selected to be different, thereby providing different appearances for the first ceramic coating 14 and the second ceramic coating 16. The second ceramic coating 16 has an initial thickness of about 0.12 mm to about 0.14 μm.

The substrate 12 with the first ceramic coating 14 and the second ceramic coating 16 is ground and polished, removing portions of the second ceramic coating 16 covering the first ceramic coating 14 and the frame portions 126 as well the outermost rough layer of the first ceramic coating 14, thereby enabling the first ceramic coating 14 and the frame portions 126 exposed out of the second ceramic coating 16. Therefore, the exterior surface of the housing 10 is comprised of three distinct materials, e.g., one metal and two different appearing ceramics, and patterns or logos may be formed thereby. Both the first ceramic coating 14 and the second ceramic coating 16 may have a thickness of about 0.1 mm to about 0.12 mm and a surface roughness Ra of about 0.1 μm to about 0.3 μm by this step.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A housing for electronic device, comprising:
a metal substrate having an outer surface, the outer surface having a plurality of concave portions and a plurality of frame portions among the concave portions, the concave portions divided into a plurality of first pattern areas and a plurality of second pattern areas;
a first ceramic coating directly formed in each first pattern area of the concave portions; and
a second ceramic coating directly formed in each second pattern area of the concave portions, the second ceramic coating and the first ceramic coating having different appearances.

2. The housing as claimed in claim 1, wherein the concave portions are concave-down relative to the frame portions.

3. The housing as claimed in claim 1, wherein the first ceramic coating and the second ceramic coating are coplanar with the frame portions.

4. The housing as claimed in claim 1, wherein the frame portions are strip-shaped and intersect with each other.

5. The housing as claimed in claim 1, wherein the first pattern areas and the second pattern areas are alternatively arranged.

6. The housing as claimed in claim 1, wherein the first pattern areas and the second pattern areas cooperatively depict a first pattern.

7. The housing as claimed in claim 6, wherein the frame portions cooperatively depict a second pattern.

8. The housing as claimed in claim 1, wherein the concave portions have a surface roughness Ra of about 1.3 μm to about 2.0 μm.

9. The housing as claimed in claim 1, wherein the first ceramic coating and the second ceramic coating are made of different ceramic oxide materials.

10. The housing as claimed in claim 9, wherein the first ceramic coating and the second ceramic coating are made from different ceramic materials selected from the group consisting of aluminum oxide, ferroferric oxide, and titanium oxide.

11. The housing as claimed in claim 1, wherein the first ceramic coating and the second ceramic coating each has a thickness of about 0.1 mm to about 0.12 mm.

12. A method for making a housing for electronic device, comprising:
providing a metal substrate having an outer surface;
etching portions of the outer surface, the etched portions forming concave portions and non-etched portions forming frame portions, the concave portions divided into first pattern areas and second pattern areas;
forming a first ceramic coating in the first pattern areas by a first thermal spraying of the outer surface;
forming a second ceramic coating covering the second pattern areas by a second thermal spraying of the outer surface having the first ceramic coating, the frame portions, the second ceramic coating and the first ceramic coating having different appearances;
grinding and polishing the substrate to expose the first ceramic coating and the frame portions out of the second ceramic coating.

13. The method as claimed in claim 12, wherein before the grinding and polishing step, the first ceramic coating has an initial thickness equal to or lager than the etching depth of the etching step.

14. The method as claimed in claim 13, wherein the before the grinding and polishing step, the first ceramic coating has an initial thickness of about 0.12 mm to about 0.14 mm.

15. The method as claimed in claim 13, wherein the etching step creates a etching depth of about 0.1 mm to about 0.12 mm.

16. The method as claimed in claim 12, wherein each of the first thermal spraying and the second thermal spraying is a flame spraying using oxygen-ethyne as fuel gas, air as conveying gas, and using a ceramic oxide material as spraying material.

17. The method as claimed in claim 16, wherein the spraying materials for the second thermal spraying and the first thermal spraying have different colors.

18. The method as claimed in claim 17, wherein the spraying materials for the first thermal spraying and the second thermal spraying are different materials selected from the group consisting of aluminum oxide, ferroferric oxide, and titanium oxide.

19. The method as claimed in claim 12, further comprising roughening the outer surface between the etching step and the first thermal spraying step.

20. The method as claimed in claim 12, wherein during the first thermal spraying, a shield having a plurality of holes is used to mask the outer surface, the holes cooperatively depict a pattern corresponding to the first pattern areas.
